(19) United States
(12) Patent Application Publication
(10) Pub. No.: US 2005/0007858 A1
(43) Pub. Date: Jan. 13, 2005

(54) Method and system for reducing power when writing information to MRAM

(76) Inventor: Kenneth K. Smith, Boise, ID (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/617,906

(22) Filed: Jul. 10, 2003

(51) Int. Cl. G11C 5/00

(52) U.S. Cl. 365/227

(57) ABSTRACT

An embodiment of the invention provides a system and method for reducing power in MRAM. A RAM buffer is used to store information. The information stored in the RAM buffer is written to MRAM such that all storage cells connected to a selected wordline in the MRAM are written. In addition, the number of power-up sequences required to write information to the MRAM is reduced.

### FIELD OF THE INVENTION

This invention relates generally to MRAM power. More particularly, this invention relates to reducing power when writing information to MRAM.

### BACKGROUND OF THE INVENTION

MRAM (magnetoresistive random access memory) is a method of storing data bits using magnetic state instead of electrical charge used by DRAM (dynamic random access memory) or SRAM (static random access memory), for example. Because an MRAM may be designed to have relatively fast read access times, similar to the access times of static RAMs, and have relatively high information density, similar to the information density of DRAMs, MRAM may be used to significantly improve electronic products by storing greater amounts of information while enabling it to be accessed faster. Manufacturers claim that by manufacturing MRAM on leading-edge processes, they can deliver speeds fast enough to displace DRAM, flash-memory chips, and all but the fastest SRAM devices.

In addition, MRAM retains its information after power is removed from the MRAM. Conventional RAM chips store information as long as power is applied to them. Once power is turned off, the information in conventional RAM is lost unless the information has been copied to a hard drive, floppy disk, or some other medium. Replacing RAM with MRAM could prevent information loss and enable computers to start up faster, without waiting for software to boot up.

In applications where low power is important, such as portable PCs, cell-phones or battery-powered devices, MRAM would significantly reduce the amount of power used. When these devices are not active, information may be stored in MRAM and power to MRAM may be turned off. When the device is activated, power is restored to the MRAM and the device may access information from the MRAM.

While an MRAM usually does not require power to retain information, an MRAM generally requires more energy than a DRAM or SRAM to write equivalent amounts of information. The amount of current required to write a stable MRAM cell can be between 2 mA and 10 mA. This is significant compared to 200 nA or less that may be required to write an SRAM cell.

In addition, the power used to write an SRAM can be self-limited. The write cycle on an SRAM only uses as much current as necessary and then automatically stops. On MRAM currently, there is no known self-limiting process, therefore a large current may flow for a predetermined amount of time. Published studies suggest that this time may be from 10 ns to 10 us. As a result, the energy required to write MRAM may be orders of magnitude larger than that of SRAM.

There is a need in the art to reduce the power consumed when writing to MRAM. An embodiment of this invention reduces the power used by MRAM during a write cycle by storing information from several writes in an SRAM buffer and later writing a large block of information from the SRAM buffer to MRAM in one write cycle. In this way, writing more information during an individual write reduces the overhead power associated with writing a certain amount of information to MRAM. A detailed description of one embodiment of this invention is described later.

### SUMMARY OF THE INVENTION

An embodiment of the invention provides a system and method for reducing power in MRAM. A RAM buffer is used to store information. The information stored in the RAM buffer is written to MRAM such that all storage cells connected to a selected wordline in the MRAM are written. In addition, the number of power-up sequences required to write information to the MRAM is reduced.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1 is a block diagram of a MRAM array with 256 bits/wordline and a write select block that supports 32-bit writes. Prior Art

FIG. 2 is a block diagram of four MRAM arrays that are driven by common wordline signals and four write select blocks. Prior Art

FIG. 3 is a block diagram of a MRAM array where all 256 bits on a wordline are written concurrently.

FIG. 4 is a block diagram of four MRAM arrays where 512 bits are written to four wordlines concurrently.

FIG. 5 is a block diagram of a MRAM array, a write select block, write voltage generator, and a timing waveform. Prior Art

FIG. 6 is a block diagram of a MRAM array, a write voltage generator, and a timing waveform.

FIG. 7 is a block diagram of a RAM buffer, an MRAM, and timing waveform for each.

FIG. 8 is a schematic describing an embodiment of a write circuit used to write a wordline on a MRAM.

### DETAILED DESCRIPTION OF THE PREFERRED EMBODIMENT

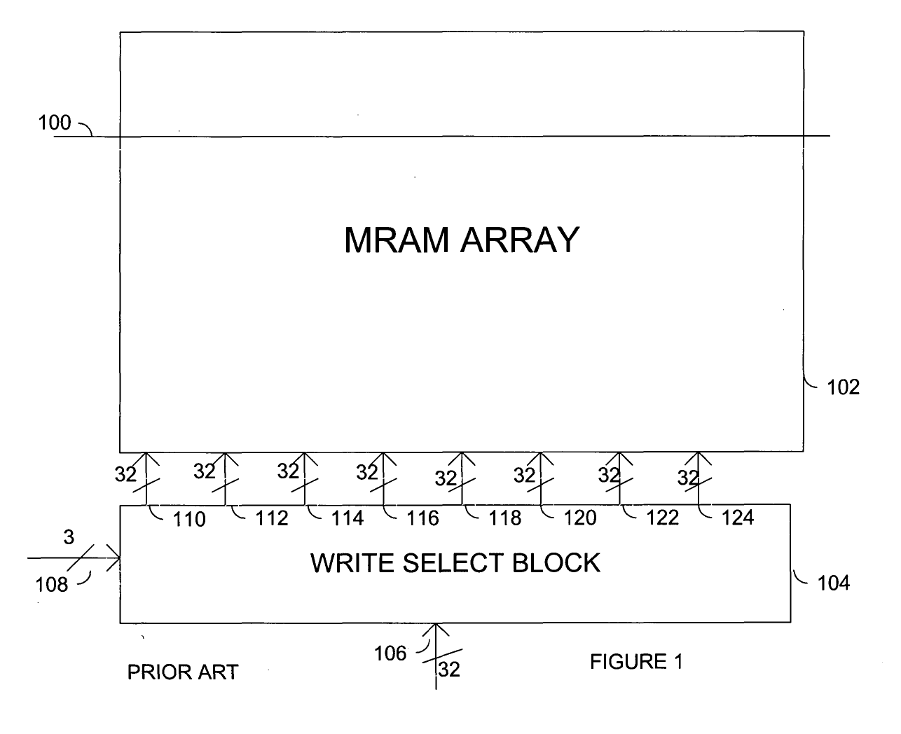

FIG. 1 is a block diagram of a MRAM array, 102, with 256 bits/wordline, 100, and a write select block, 104 that supports 32-bit writes. The select signal, 108, selects which group of 32 bits, 110, 112, 114, 116, 118, 120, 122, or 124, is written by the 32-bit input, 106. In order to write all 256 bits to a selected wordline, 100, each group of 32 bits, 110, 112, 114, 116, 118, 120, 122, and 124 must be written to by the 32-bit input, 106. Writing to all eight 32-bit groups requires current to be driven through wordline, 100, eight times. The power required to write to a wordline on a MRAM is orders of magnitude higher than writing to an equivalent wordline on an SRAM or DRAM. As a consequence, power would be saved if all the bits on a wordline in a MRAM were written at the same time.

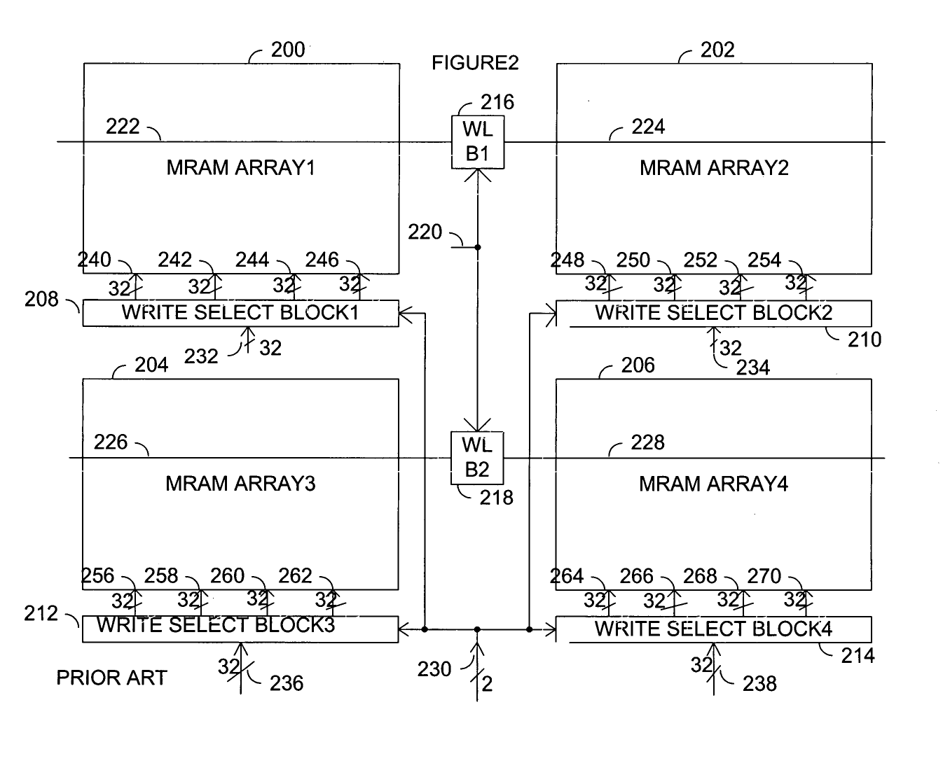

FIG. 2 is a block diagram of four MRAM arrays, 200, 202, 204, and 206, that are driven by a common wordline signal, 220 and four write select blocks, 208, 210, 212, and 214. The wordline signal, 220, drives two wordline buffers, 216 and 218. Wordline buffer 216 drives wordlines 222 and 224. Wordline buffer 218 drives wordlines 226 and 228. The select signal, 230, selects which group of 32 bits, 240, 242, 244, or 246, is written by the 32-bit input, 232, of write select block1, 208. The select signal, 230, selects which group of 32 bits, 248, 250, 252, or 254, is written by the 32-bit input, 234, of write select block2, 210. The select signal, 230, selects which group of 32 bits, 256, 258, 260, or 262, is written by the 32-bit input, 236, of write select block3, 212. The select signal, 230, selects which group of 32 bits, 264, 266, 268, or 270, is written by the 32-bit input, 238, of write select block4, 214.

In order to write all 512 bits on the wordlines, 222, 224, 226, and 228, selected by wordline signal 220, each group of 32 bits on each write select block, 208, 210, 212, and 214, must be written to by each of the 32-bit inputs, 232, 234, 236, and 238, respectively. Writing to all sixteen 32-bit groups requires current to be driven through the wordlines, 222, 224, 226, and 228 four times. The power required to write to a wordlines on a MRAM is orders of magnitude higher than writing to an equivalent wordline on an SRAM or DRAM. As a consequence, power would be saved if all the bits on a wordline on a MRAM were written at the same time.

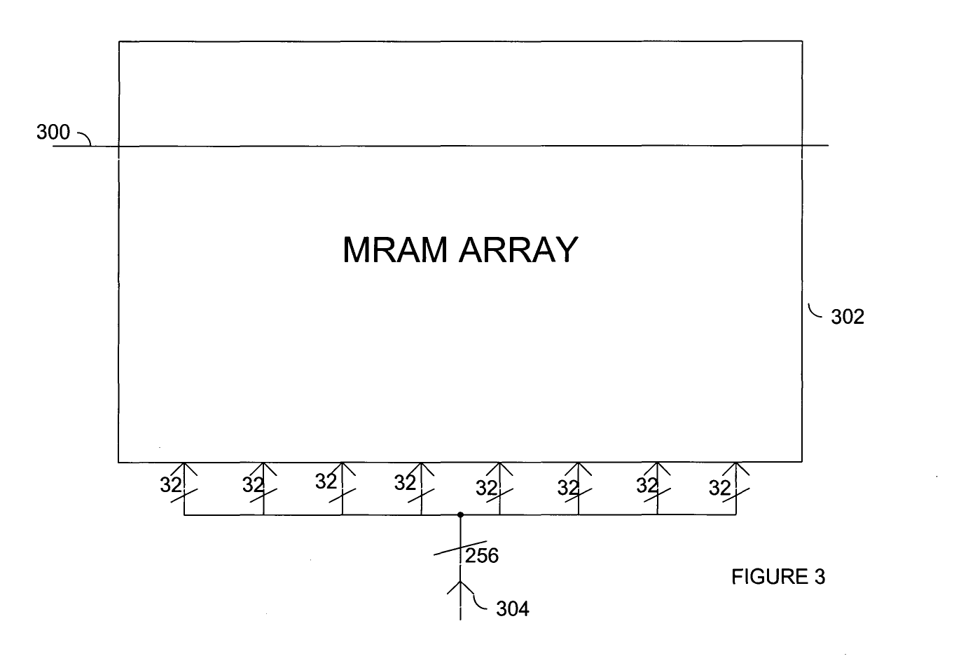

FIG. 3 is a block diagram of a MRAM array, 302, where all 256 bits, 304, on a wordline, 300, are written concurrently. By writing all the bits on a wordline, 300, concurrently, the wordline, 300, only has current driven through it one time. If the 256 bits on the wordline, 300, were written 32 bits per cycle, the wordline would have current driven through it eight times in order to write all 256 bits. As a consequence, the power required to drive current through a wordline on a MRAM would be reduced by a factor of eight in this example. Since the power required to write to a wordline on a MRAM is orders of magnitude higher than writing to an equivalent wordline on an SRAM or DRAM, a reduction in the power used to drive current through the wordlines on a MRAM can be significant.

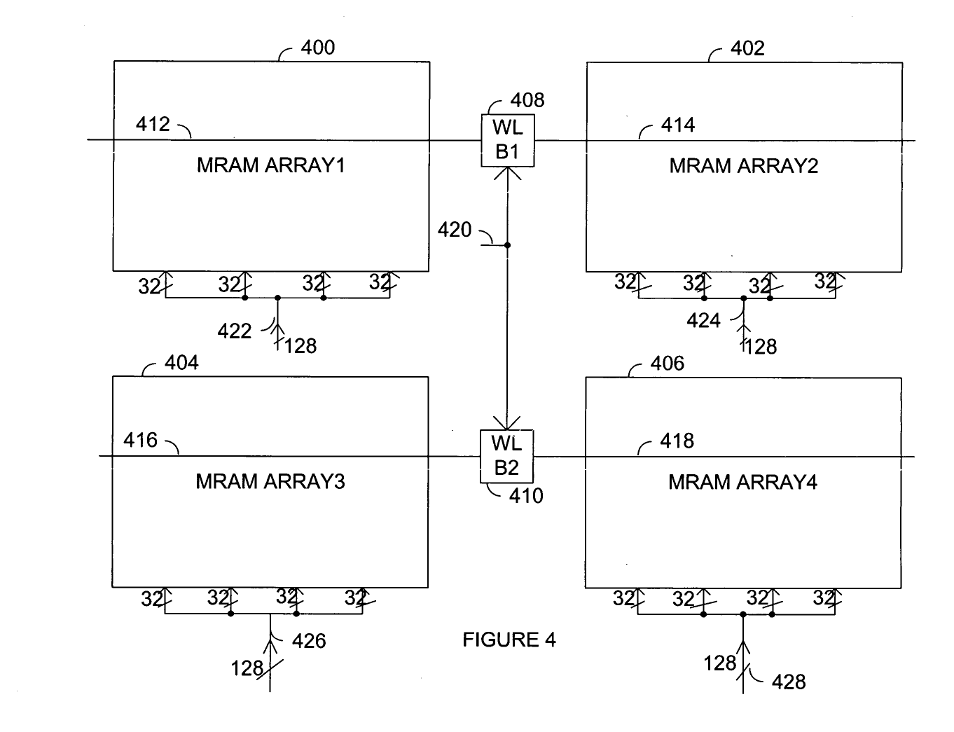

FIG. 4 is a block diagram of four MRAM arrays, 400, 402, 404, and 406, where 512 bits are written to four wordlines, 412, 414, 416, and 418 concurrently. Wordline signal 420 drives wordline buffers, 408 and 410. Wordline buffer1, 408, drives wordlines, 412 and 414. Wordline buffer2, 410, drives wordlines 416 and 418. When wordline 412 is selected, all 128 bits, 422, on wordline 412 can be written. When wordline 414 is selected, all 128 bits, 424, on wordline 414 can be written. When wordline 416 is selected, all 128 bits, 426, on wordline 416 can be written. When wordline 418 is selected, all 128 bits, 428, on wordline 418 can be written. By selecting wordline signal 420, 512 bits may be written in one cycle and wordlines, 412, 414, 416, and 418, only have current driven through them one time.

If the 512 bits on the wordlines, 412, 414, 416, and 418, are written 128 bits per cycle, the wordlines, 412, 414, 416, and 418 would have current driven through them four times in order to write all 512 bits. As a consequence, the power required to drive current through wordlines on a MRAM would be reduced by a factor of four in this example. Since the power required to write to a wordline on a MRAM is orders of magnitude higher than writing to an equivalent wordline on an SRAM or DRAM, a reduction in the power used to charge wordlines on a MRAM can be significant.

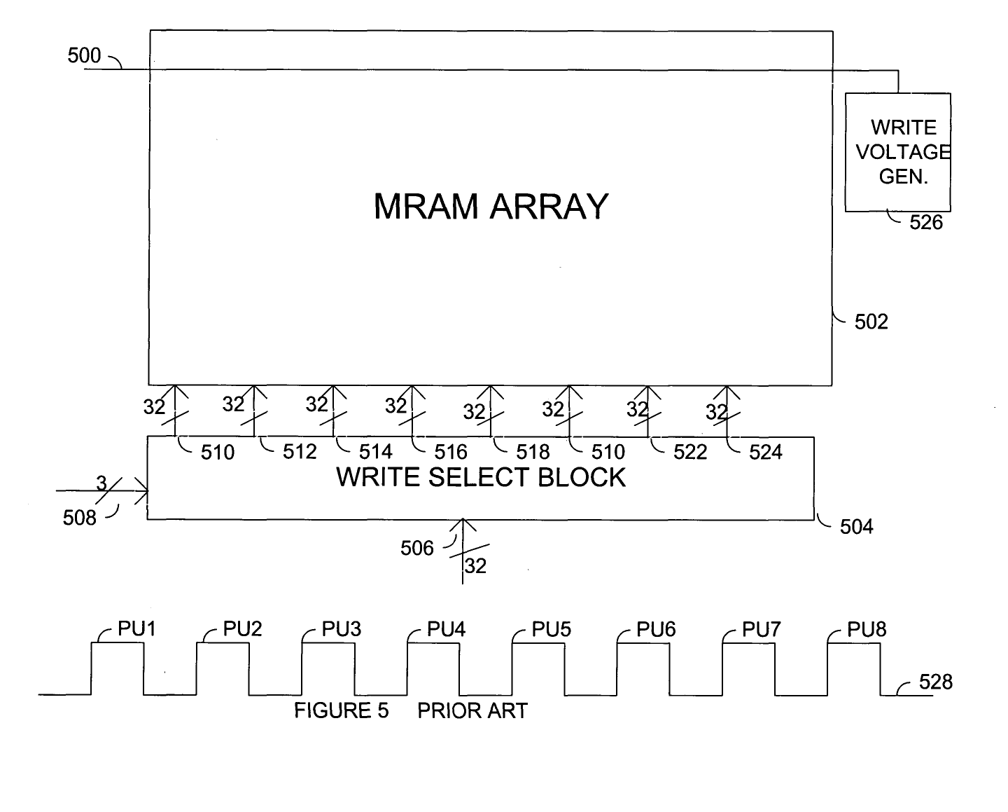

FIG. 5 is a block diagram of a MRAM array, 502, a write select block, 504, write voltage generator, 526, and a timing waveform, 528. To obtain reliable writes, the write voltage applied to one end of the write conductor must be very precisely controlled. The write voltage is typically not equal to the supply voltage for the design. Voltages greater in magnitude than the supply voltage are generally required due to the high write currents. An example would be if 2 mA was driven through a write line, and the write line has a resistance of 2k-ohms, then 4 Volts would be required just for the write line. When the “on-voltages” of the write transistors are incorporated, the required voltage would be around 6 Volts. Typical sub-micron IC designs operate on supply voltages of 3.3V or less. Voltage generators that create higher voltages than the power supply are not 100% efficient, and therefore lose energy whenever enabled. Also, if the write voltage is less than the power-supply, it will not be 100% efficient, and will expend energy whenever it is enabled.

In addition to reducing the power required to drive current through the wordlines, writing more bits per cycle to a wordline on a MRAM reduces the overhead power required to power circuitry associated with writing wordlines on a MRAM. For example, in order to write 256 bits to wordline 500, there must be eight write cycles, 528. During these eight write cycles, 528, the write voltage generator, 526 may either be powered up and down eight times, or left enabled for the entire duration of the eight writes cycles and idle times between them. In this example, the power required by the write voltage generator, 526, is at least eight times greater than if all 256 bits were written to the wordline, 500, on one cycle.

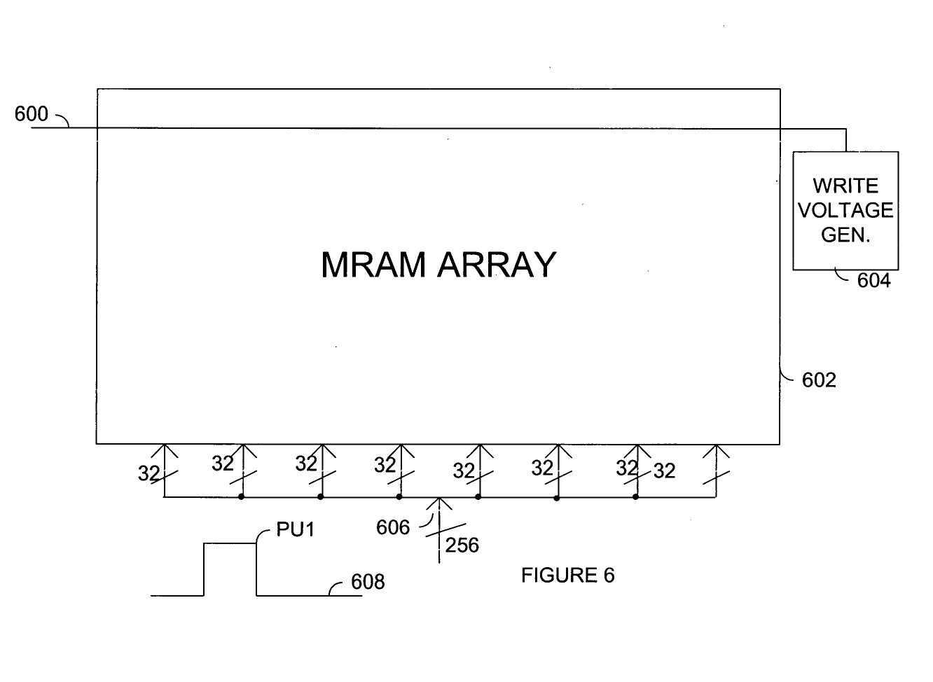

FIG. 6 is a block diagram of a MRAM array, 602, a write voltage generator, 604, and a timing waveform, 608. In this example, 256 bits, 606 are written to the wordline, 600, in one cycle, 608. As a result, only one power up and down cycle of the write voltage generator, 605, is required. This reduces the power used by the write voltage generator to write 256 bits by a factor of eight.

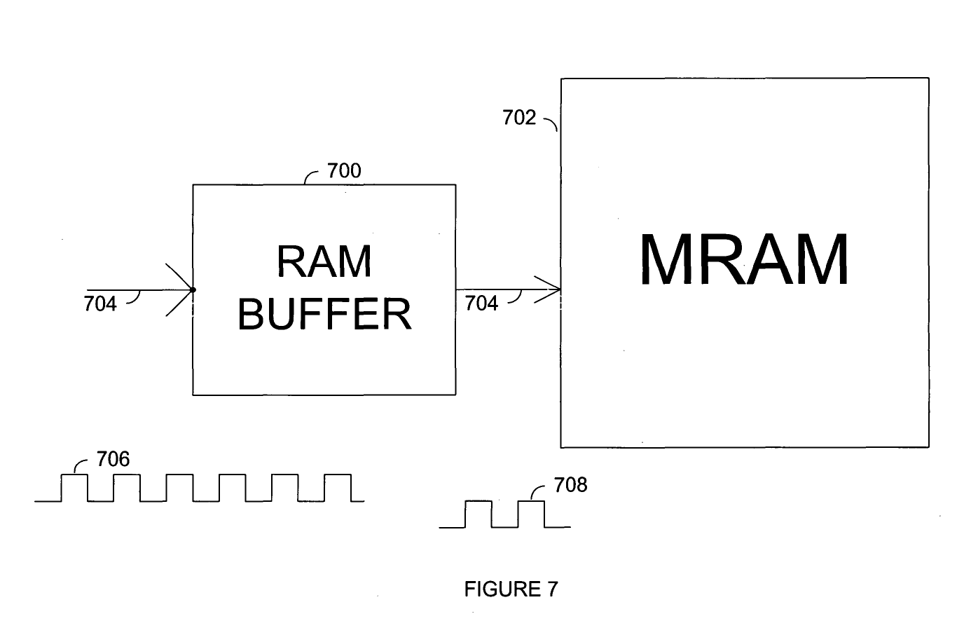

FIG. 7 is a block diagram of a RAM buffer, 700, an MRAM, 702 and timing waveform for each, 706 and 708, respectively. At a system level, the size of data words written to memory can vary in size. As consequence, one embodiment of this invention stores a specified amount of information over several cycles, 706, in a RAM buffer, 704. After storing the specified amount of information in RAM buffer, 700, the specified amount of information is read from the RAM buffer, 700, and written to the MRAM, 702, using fewer cycles, 708, than were used to store the specified amount of information in RAM buffer, 700. Because fewer cycles are used to store the specified amount of information in the MRAM, 702, than were used to store the specified amount of information in the RAM buffer, 700, less power is used to drive current through the associated wordlines, charge the write voltage generator, and other circuitry used to write information to a MRAM, 702.

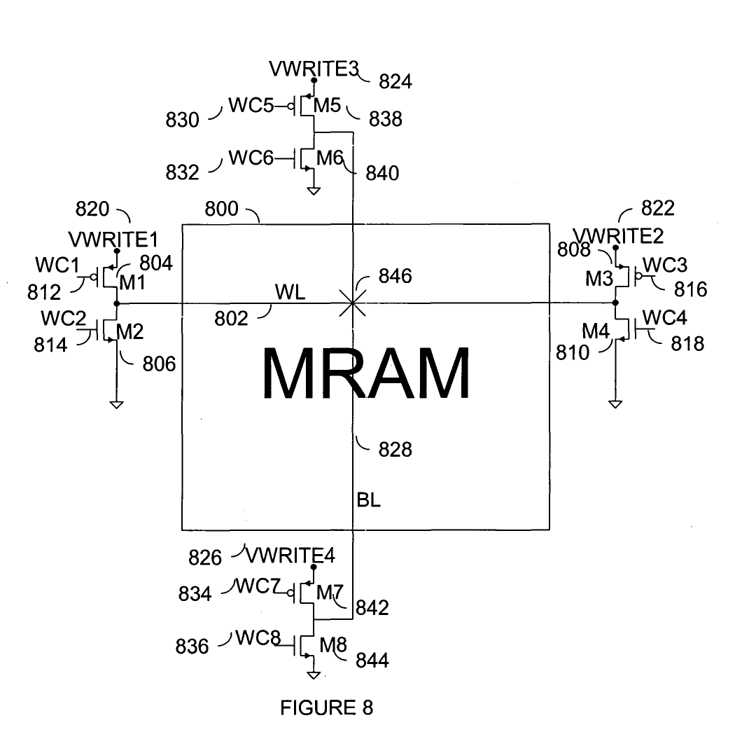

FIG. 8 is a schematic describing an embodiment of a write circuit used to write a wordline, WL, 802, and a bitline, 828 on a MRAM, 800. The supply voltages applied to the sources of PFET M1, 804, and PFET M3, 808, are VWRITE1, 820, and VWRITE2, 822 respectively. The supply voltages, VWRITE1, 820, and VWRITE2, 822, may be equal or different depending on the symmetry of the magnetic bits. Current is conducted through PFET, M1, 804, through the WL, 802, through NFET, M4, 810 to ground when signal WC1, 812, is low, signal WC4, 818 is high, signal WC2, 814 is low, and signal WC3, 816 is high. Current is conducted through PFET, M3, 808, through the WL, 802, through NFET, M2, 806 to ground when signal WC1, 812, is high, signal WC4, 818 is low, signal WC2, 814 is high, and signal WC3, 816 is low. In this way, current may be conducted in either direction on the WL, 802. A wordline may be used for writing only or it may be used for both reading and writing.

The supply voltages applied to the sources of PFET M5, 838, and PFET M7, 842, are VWRITE3, 824, and VWRITE4, 826 respectively. The supply voltages, VWRITE3, 824, and VWRITE4, 826, may be equal or different depending on the symmetry of the magnetic bits. Current is conducted through PFET, M5, 838, through the BL, 828, through NFET, M8, 844 to ground when signal WC5, 830, is low, signal WC8, 836 is high, signal WC6, 841 is low, and signal WC7, 834 is high. Current is conducted through PFET, M7, 842, through the BL, 828, through NFET, M6, 840 to ground when signal WC5, 830, is high, signal WC8, 836 is low, signal WC6, 832 is high, and signal WC7, 834 is low. In this way, current may be conducted in either direction on the BL, 828.

The current flow through the wordline, WL, 802 and bitline, BL, 828 create magnetic fields. These magnetic fields are able to set or reverse the magnetic field present in a MRAM bit, 846.

In the example shown in FIG. 8, PFETS, 804 and 808, and NFETS, 806 and 810, were used to implement write circuitry for a MRAM wordline, WL, 802. Other types of transistors may be used to implement this circuit. For example, bipolar and JFET (Junction Field Effect Transistors) devices may be used.

The foregoing description of the present invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

1) A method for reducing power in MRAM comprising:
(a) storing information in a RAM buffer;
(b) reading the information from the RAM buffer;
(c) writing the information to the MRAM;
(d) such that all storage cells connected to a selected wordline in the MRAM are written.

2) The method in claim 1 wherein the RAM buffer is an SRAM buffer.

3) The method in claim 1 wherein the RAM buffer is a DRAM buffer.

4) The method in claim 1 wherein the RAM buffer is an array of flip-flops.

5) A method for reducing power in MRAM comprising:
(a) storing information from N write cycles in a RAM buffer;
(b) reading the information from the RAM buffer using fewer than N read cycles;
(c) writing the information to the MRAM using fewer than N write cycles;
(d) such that the number of power-up sequences required to write the information to the MRAM is reduced.

6) The method in claim 5 wherein the RAM buffer is an SRAM buffer.

7) The method in claim 5 wherein the RAM buffer is a DRAM buffer.

8) The method in claim 5 wherein the RAM buffer is an array of flip-flops.

9) A method for reducing power in MRAM comprising:
(a) storing information from N write cycles in a RAM buffer;
(b) reading the information from the RAM buffer using one read cycle;
(c) writing the information to the MRAM using one write cycle;
(d) such that only one power-up sequence is used to write the information to the MRAM.

10) The method in claim 9 wherein the RAM buffer is an SRAM buffer.

11) The method in claim 9 wherein the RAM buffer is a DRAM buffer.

12) The method in claim 9 wherein the RAM buffer is an array of flip-flops.

13) A system for reducing power in MRAM comprising:
(a) a RAM buffer;
(b) a MRAM;
(c) wherein the RAM buffer stores information;
(d) wherein the information stored in the RAM buffer is written to the MRAM such that all storage cells connected to a selected wordline in the MRAM are written.

14) The system in claim 13 wherein the RAM buffer is an SRAM buffer.

15) The system in claim 13 wherein the RAM buffer is a DRAM buffer.

16) The system in claim 13 wherein the RAM buffer is an array of flip-flops.

17) A system for reducing power in MRAM comprising:
(a) a RAM buffer;
(b) a MRAM;
(c) wherein the RAM buffer stores information for N cycles;
(d) wherein the information stored in the RAM buffer is written to the MRAM in less than N cycles;
(e) wherein the number of power-up sequences required to write the information to the MRAM is reduced.

18) The system in claim 17 wherein the RAM buffer is an SRAM buffer.

19) The system in claim 17 wherein the RAM buffer is a DRAM buffer.

20) The system in claim 17 wherein the RAM buffer is an array of flip-flops.

21) A system for reducing power in MRAM comprising:
(a) a RAM buffer;
(b) a MRAM;
(c) wherein the RAM buffer stores information for N cycles;
(d) wherein the information stored in the RAM buffer is written to the MRAM in one cycle;
(e) wherein only one power-up sequence is required to write the information to the MRAM.

22) The system in claim 21 wherein the RAM buffer is an SRAM buffer.

23) The system in claim 21 wherein the RAM buffer is a DRAM buffer.

24) The system in claim 21 wherein the RAM buffer is an array of flip-flops.

25) A system for reducing power in MRAM comprising:
(a) a means for electronically reading and writing information;
(b) a MRAM;
(c) wherein the means for electronically reading and writing information stores information for N cycles;
(d) wherein the information stored in the means for electronically reading and writing information is written to the MRAM in less than N cycles;
(e) wherein the number of power-up sequences required to write the information to the MRAM is reduced.
